(19) United States
(12) Patent Application Publication
(10) Pub. No.: US 2025/0306096 A1
(43) Pub. Date: Oct. 2, 2025

(54) METHOD AND APPARATUS FOR DYNAMICALLY CONFIGURING ELECTRONIC INSTRUMENTATION

(71) Applicant: Xyratek Limited, Suffolk (GB)

(72) Inventor: Stuart VANT, Suffolk (GB)

(21) Appl. No.: 19/080,881

(22) Filed: Mar. 16, 2025

(30) Foreign Application Priority Data
Mar. 27, 2024 (GB) 2404421.6
Nov. 12, 2024 (GB) 2416636.5

(51) Int. Cl. G01R 31/317

(52) U.S. Cl. CPC G01R 31/31713

(57) ABSTRACT

An electronic test equipment system includes: a user interface; and a dynamically configurable multi-instrument operably coupleable to the user interface. A processor is arranged to apply at least one control signal to a software configurable switch that connects at least one selectable item of test equipment of at least one of: dynamically configurable digital logic circuitry, dynamically configurable analogue circuitry, to at least one individual input-output, IO, of an IO interface that re-configures the dynamically configurable multi-instrument to function as a different measurement or test instrument for a device under test.

### FIELD OF THE INVENTION

The field of the invention relates to electronic test equipment system and a method for performing electronic instrumentation testing. The invention is applicable to, but not limited to, dynamically configuring electronic instrumentation in a laboratory environment or remotely.

### BACKGROUND OF THE INVENTION

Electronic Instrumentation is a term used for the design, realisation and use of electronic systems for the measurement of electrical and/or non-electrical quantities. The activity that typically forms the basis of electronic instrumentation, often performed in a laboratory setting, is measuring. An electronic instrumentation system is an assembly of various devices (or components) configured to form a measurement device, for observation, monitoring and/or control purposes, typically of a device-under-test (DUT). The basic building blocks for an electronic instrumentation system include: a sensor, signal processing, and a display for monitoring/measuring such a DUT. In its simplest form, the well-known multi-meter, which is capable of measuring, resistance, voltage (alternating current (AC) and direct current (DC)) and usually current, may be considered as a simple form of electronic instrumentation system.

It is known that electronic/test engineers regularly use multiple pieces of electronic instrumentation in order to measure and/or control various signals, values/levels or quantities in, say, circuits or components or systems that they are working on. However, it is known that electronic engineers regularly need to reconfigure both the multiple instruments (e.g., instrumentation system) themselves and how they are connected to the DUT.

Furthermore, electronic/test engineers frequently need to perform more than one measurement on one particular aspect of a DUT or to measure multiple devices or circuit functions in order to characterize them. This necessitates moving connections between either multiple pieces of instrumentation or multiple devices or both. An example of this might be, say, if the device under test for one particular test requires a direct current (dc) signal to be applied to one node whilst measuring a dc output from another node, but then requires that the connections be swapped over for a different test. This necessitates that the electronic/test engineer either manually moves the connections around or creates some sort of switching apparatus specific to this particular test set-up. Moving the connections manually is the easiest and most flexible approach; however, it occupies the engineer's time ineffectively, whereas designing and building dedicated switching equipment frees up the electronic/test engineer for the testing process, but requires significant time and resources to create something that is of no value after the testing is complete.

It is known that there are some specific items of test instrumentation that incorporate rudimentary switching capabilities, but only within the boundaries of one particular instrumentation function. Keysight 34970 is a Data acquisition switch unit that is equivalent to a common multi-meter, but provides the ability to select up to 60 measurement points to be connected to the one multimeter using software control. Most network analyzers allow the source and measurement nodes to be automatically selected from either two or four instrumentation ports.

Whilst modern electronic instruments can often be remotely controlled, any physical connection between multiple electronic instruments needs to be manually attached and moved around. This necessitates a physical presence of the test engineer around a device-under-test that is being tested for a variety of performance statistics. The inventor has recognised and appreciated that it would be desirable to have more flexibility when using multiple electronic instruments, with a greater degree of automated operation.

Accordingly, there is a need for an apparatus for testing and method for performing electronic instrumentation testing and/or control of a device-under-test.

### SUMMARY OF THE INVENTION

Aspects herein described provide an apparatus for testing and method for performing electronic instrumentation testing and/or control of a device-under-test, as described in the accompanying claims. Specific embodiments of the invention are set forth in the dependent claims. These and other aspects will be apparent from and elucidated with reference to the embodiments described hereinafter.

### BRIEF DESCRIPTION OF THE DRAWINGS

Further details, aspects and examples will be described, by way of example only, with reference to the drawings. In the drawings, like reference numbers are used to identify like or functionally similar elements. Elements in the figures are illustrated for simplicity and clarity purposes only, and have not necessarily been drawn to scale.

FIG. 1 illustrates a simplified drawing of an electronic test equipment system, adapted according to examples of the invention.

FIG. 2 illustrates one example mechanism by which typical discrete pieces of test equipment can be formed from simplistic analogue building blocks connected-in digital hardware (HW).

FIG. 3 illustrates one example mechanism by which multiple pieces of test equipment might be contained within the boundary of a larger system and connected to one or more DUTs via a cross bar of analogue switches.

FIG. 4 illustrates a mechanism for dynamically (re-)configuring the electronic test equipment system of FIG. 1 and/or FIG. 2 and/or FIG. 3, and the (re-)configuring of connections between the electronic test equipment system and a device-under-test through software control, adapted according to examples of the invention.

### DETAILED DESCRIPTION

Examples herein described effectively provide an electronic test equipment system that includes multiple unique, different items of (re-)configurable test equipment (in a physical box) and allows the connectivity both between them and a device-under-test to be dynamically reconfigured through software control. For example, the electronic test equipment system having dynamically configurable multi-instrument that includes dynamically configurable digital logic circuitry and/or dynamically configurable analogue logic circuitry may include one or more of the following: power supplies, source measure units, arbitrary waveform generators, oscilloscopes, digital multi-meters (DMMs), logic analysers, digital pattern generators, protocol specific debug tools (such as Joint Test Action Group (JTAG) pods, inter-integrated circuit (I2C) debuggers (where I2C is a two-wire serial communication protocol using a serial data line (SDA) and a serial clock line (SCL)), etc.

In one example, the electronic test equipment system may require that a majority (or in some examples, all) of the input-output (IO) connections to the dynamically configurable multi-instrument may be arranged to be common and equal, such that the connectivity is completely software defined and dynamically reconfigurable via, in some examples, a cross-bar switching circuit. In this manner, for example, an IO pin may be dedicated/configured as a simple oscilloscope IO. However, a user or test engineer may then be able to re-configure this IO pin, for example switch its functionality to another function, for example in response to a predetermined event happening. Thus, in effect in some examples, a finite amount of instrumentation equipment is made available, for example in an array manner, using a finite number of real IO connections, with a non-blocking fully populated crossbar switch located between them.

Examples herein described aim to solve or ease the aforementioned problems through a use of highly configurable digital logic circuitry and/or configurable analogue logic circuitry arranged to achieve the same or similar capabilities of multiple existing instruments working independently. In this manner, multiple instances of test equipment can be provided in, say, a single physical box that allows the connectivity both between the test equipment and the device-under-test, where the test equipment can be dynamically reconfigured through software control, with tighter cohesion. In this manner, the examples described herein may provide a better cost-to-functionality ratio than the current approach of using discrete (non-reconfigurable pieces of test equipment.

In some examples, the reconfigurable pieces of test equipment may be arranged to facilitate multiple different measurements of a DUT and may be applied to the following situations. In a first envisioned example, an electronic/test engineer may wish to monitor the current that is being drawn by a DUT, say using a current metering instrument, and monitor this value in software. If the DUT draws an excessive current (for example due to a fault condition), the software, written by the electronic/test engineer, would shut-down the power supply to the DUT in order to limit the amount of damage caused during this identified fault condition and, say, to reduce fire risks and aid in better fault analysis of the DUT by reducing the damage caused by the excess current drawn. In a second envisioned example, a DUT may be driven with a particular signal in an attempt to trigger a condition or event within the DUT, which may require further analysis. The electronic/test engineer may then believe it is desirable to remove the signal and measure some other characteristic of the DUT, with different instrumentation at the same physical point on the DUT. This would normally require the creation of dedicated switching HW and control software or systems. However, employing examples described herein, such re-configurability of the test equipment, may yield the aforementioned benefits within a single instrument, with software-controlled re-configuration and without the creation of dedicated HW, which would have little/no residual value after the measurements were taken.

Furthermore, some examples provide dynamic fast loading of the digital logic, which in some examples is specifically loaded in relation to the case of bench instrumentation. Also, a skilled artisan will appreciate that using fewer pieces of test equipment, but where the pieces of test equipment can be re-configured to perform other functions, less bench space needs to be used by the electrical/test engineer. In some examples, concepts herein described may provide tighter and better interoperability between the pieces of test equipment, for example, the configuration of a first item of re-configurable test equipment may be dynamically changed based upon the measurements performed by a second item re-configurable of test equipment. For example, a first discrete item of test equipment employed by an electrical/test engineer, which includes say a power supply, oscilloscope, digital multimeter (DMM), etc., may assist in performing a first measurement or multiple measurements. This first discrete test equipment unit may then be dynamically re-configured (e.g., by dynamically changing the connectivity using a cross-bar switch) to additionally connect to separate standard test equipment, e.g., to a PC via a universal serial bus (USB) or Ethernet. With this dynamic re-configurability option, the electrical/test engineer is able to write software code that, for example, powers on the DUT and waits for it to, say, emit a pulse and when it emits the pulse the software code may poll the oscilloscope to detect the pulse and then re-program the power supply to change the DUT supply voltage slightly.

Using the examples herein-described, this change in a measurement may take at best tens of milli-seconds, due to the inherent speed of the test equipment, PC and communications interfaces, which could also algorithmically generate a waveform based upon multiple measurements from multiple instruments within the HW. Without employing the techniques described herein, the electrical/test engineer will need to design and build a dedicated piece of test equipment to perform this one specific task, as for example generating a waveform on-the-fly based upon measurements is currently impossible to do with current test equipment.

In some examples, concepts herein described provide faster reconfigurability of instrumentation equipment, as connections between the DUT and instruments may be changed, re-configured and controlled in software, using a crossbar switch, rather than having to physically move cables around and attach the DUT to multiple different pieces of test equipment.

In some examples, concepts herein described provide an ability to merge measurements, for example to measure DUT consumed power, such that the measured supplied voltage and supply current may be multiplied together to obtain a DUT consumed power. Alternatively, and/or additionally, the software may be employed to control the measurements being made, for example to measure the output of the DUT if it unexpectedly consumes more power supply power. Otherwise, the test equipment may not be concerned, and in such situations an output measurement of consumed supply power is only triggered if the regular supply measurements go over some defined threshold. Thus, in this manner, multiple different instruments can be combined together and processed and multiple measurements taken therefrom, nearly instantaneously, in order to obtain a more specific or customised view of the available data to the task at hand.

In some examples, concepts herein described provide an ability to move data between instruments more efficiently due to the tightly-controlled interconnection of the IOs and the supplied controlling system, as compared to using discrete pieces of test equipment. For example, in one example, it is envisaged that a pattern captured by a logic analyser may be dynamically filtered or modified and then played out in real-time by the pattern generator with very little delay and at a high data rate to a user/operator/test equipment engineer, for example via a different piece of test equipment, for example with a better screen. In this manner, examples of the present invention provide an apparatus for testing and method for performing electronic instrumentation testing and/or control of a device-under-test.

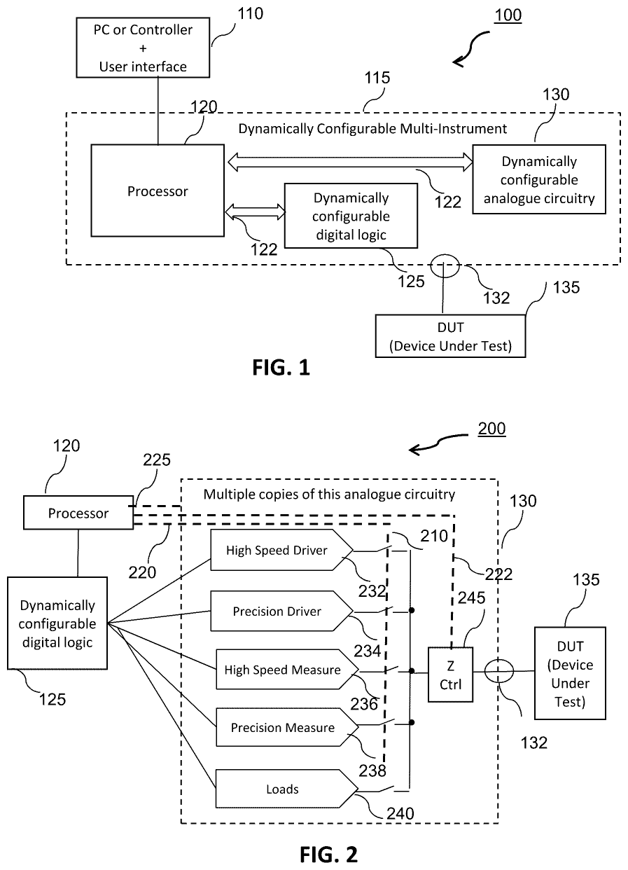

Referring now to FIG. 1, a simplified schematic of an electronic test equipment system 100 is illustrated, according to some examples. In one example, the electronic test equipment system 100 comprises a personal computer or laptop or controller and preferably a user interface 110. The electronic test equipment system 100 includes a dynamically configurable multi-instrument 115 test equipment unit, connected to the personal computer or laptop or controller and, preferably, user interface 110. In this example, at a high-level, the dynamically configurable multi-instrument 115 test equipment unit may be parsed into a processor 120 connected via a data bus 122 to at least one of, and preferably in most applications both: a dynamically configurable digital logic circuitry 125 and a dynamically configurable analogue logic circuitry 130. The processor 120 is configured to transfer data to/from the dynamically configurable digital logic circuitry 125 and dynamically configurable analogue logic circuitry 130, including configuration data in order to (re-)configure the dynamically configurable digital logic circuitry 125 and/or dynamically configurable analogue logic circuitry 130 and receive measurement data therefrom. As will be appreciated by a skilled person, it is envisaged that the dynamically configurable digital logic circuitry 125 and/or dynamically configurable analogue logic circuitry 130 may/will include one or multiple Digital-to-Analog Converters (DACs) and Analog-to-Digital Converters (ADCs) (not shown in detail solely for the sake of not obfuscating or limiting the concepts and architecture to be protected), where the DACs and ADCs may have varying performance capabilities to ensure a wide range of testing applications that may be performed by the dynamically configurable multi-instrument 115 test equipment unit. The dynamically configurable multi-instrument 115 test equipment unit also includes an input/output interface 132 (which in some examples may be an array of input/output ports) configured to be connectable to a device under test (DUT) 135.

In this example, the dynamically configurable analogue logic circuitry 130 is arranged to receive a range of analogue circuit configuration settings that may be loaded into the dynamically configurable analogue logic circuitry 130 and re-configure the dynamically configurable analogue logic circuitry 130 very quickly. For example, this speed may be similar to the in-field firmware upgrades that are commonplace on many devices. However, in accordance with some examples, the electronic test equipment system 100 is differentiated from known in-field firmware upgrades by employing a cross bar of analogue switches to facilitate a rapid re-configuration of the dynamically configurable analogue logic circuitry 130. In this manner, examples herein described no longer take multiple minutes to re-program logic circuits, which makes the logic circuits unusable for a period of time, and does not unduly disrupt the operation and use of the dynamically configurable logic. In this manner, the electronic test equipment system 100 provides several advantages, such as: the available number of features can be far greater than the physical size of the logic array, as multiple different configurations can be achieved through rapid program and re-configuration of the cross bar of analogue switches. In some examples, in effect, a much larger (albeit finite) number of configurations and capabilities can be provided to the electronic test equipment system 100.

In some examples, it is envisaged that new features or circuits can be added and/or improved and/or modified after the instrument has been placed in the field. In this manner, the electronic test equipment system 100 may be viewed as a communication cabinet with multiple insertable circuit boards, each configured to perform a specific test/measurement function. In some examples, it is envisaged that the electronic test equipment system 100 may be user-configurable, in that the electronic test equipment system 100 may be sold as an empty unit and then populated with various logic circuitry dependent upon the user requirements or selected by the user or operator. In some examples, it is envisaged that the selectable various logic circuitry may be selected on a time-limited or a capability limited license. In some examples, it is envisaged that the implementation of the electronic test equipment system 100 may include the logic ‘images’ to be encrypted at source and decrypted in the logic array/processor 120 hardware as a means to enforce copyright protection. In the context of the present invention, reference to logic ‘images’ is intended to encompass at least a binary data set that defines a configuration of the digital logic and/or the analogue circuitry, for example in a format that is proprietary/specific to the implementation.

Referring now to FIG. 2, a further example electronic test equipment system 200 by which typical discrete pieces of test equipment can be formed from analogue circuits (consider them as ‘building blocks’) connected to digital hardware (HW) is illustrated, according to some examples of the invention. In this example, the further example electronic test equipment system 200 may be viewed as multiple pieces of test equipment connected via a software configurable analogue switch 210. Thus, in this example, the electronic test equipment system 200 includes a personal computer or laptop or controller and preferably a user interface (not shown). The electronic test equipment system 200 includes a processor 120 connected to dynamically configurable digital logic circuitry 125 and optionally dynamically configurable analogue logic circuitry 130. The processor 120 is configured to transfer data to/from the dynamically configurable digital logic circuitry 125. In accordance with this example, the dynamically configurable digital logic circuitry 125 is connected to a plurality of software (SW) configurable analogue switches 210, controllable via control signals 220 by the processor 120 that is arranged to select inputs/outputs from multiple copies of a dynamically configurable analogue logic circuitry 130, in order to apply test equipment signals and/or receive measurement data therefrom. In this example, the multiple copies of a dynamically configurable analogue logic circuitry 130 may include, for example, a high-speed driver 232, a precision driver 234, a high-speed measurement circuit 236, a precision measurement circuit 238, one or more analog loads 240, etc. Each of the plurality of software (SW) configurable analogue switches 210, controllable via control signals 220, is connected to at least one individual input/output interface 132 via an impedance control circuit 245, controllable by the processor 120 using control signals 222. In one example, for the option of one or more analog loads 240, the inventor has recognised and appreciated that, in reality, Digital-to-Analog Converters (DACs) and Analog-to-Digital Converters (ADCs) do not allow for all of the desired bench instrumentation to be modelled. Hence, the inventor has recognised and appreciated that there may be a need to provide controllable loading and other resistive effects, which are supported for configurable analog loads and source impedance controls amongst any DACs and ADCs that can be configured by the processor 120.

The multiple copies of a dynamically configurable analogue logic circuitry 130 are each capable of being connected to a respective individual input/output interface 132 (which in some examples may be an individual input/output interface 132 from an array of input/output ports) configured to be connectable to a device under test (DUT) 135.

In this example, the dynamically configurable analogue logic circuitry 130 may be arranged to receive a range of analogue circuit configuration settings 225 that may be loaded into the dynamically configurable analogue logic circuitry 130 and re-configure one or more of the dynamically configurable analogue logic circuits very quickly. In this manner, by being able to individually apply settings to various circuits of the dynamically configurable analogue logic circuitry 130, and by configuring 220 the software configurable analogue switch 210 accordingly to control signals input to/output from the dynamically configurable analogue logic circuitry 130, examples herein described no longer take multiple minutes to re-program logic circuits, which makes the logic circuits unusable for a period of time, and do not unduly disrupt the operation and use of the dynamically configurable logic.

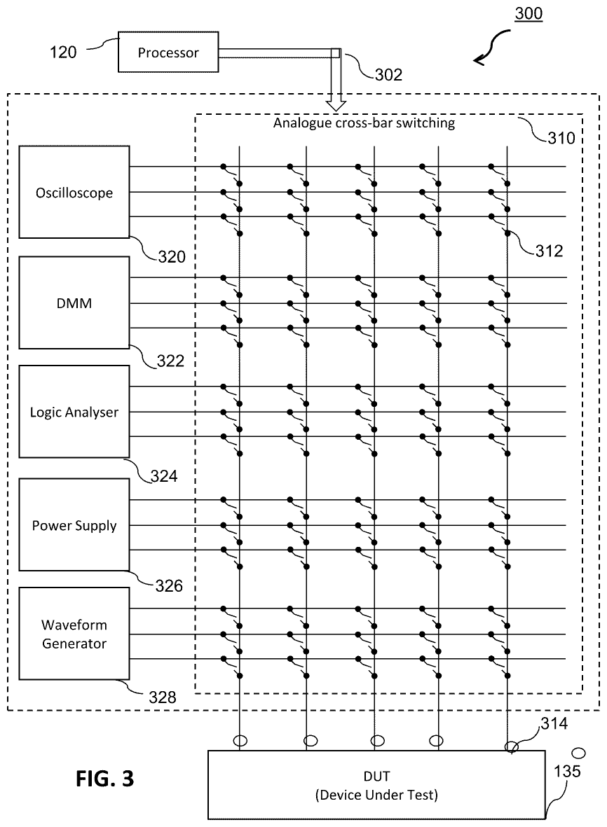

Referring now to FIG. 3, one example system architecture 300 is illustrated by which multiple pieces of test equipment, which in this example includes at least an oscilloscope 320, a DMM 322, a logic analyser 324, a power supply 326 and a waveform generator 328, are contained within the boundary of a larger system and connected via a series (or array) of input-output ports 314 to one or more DUTs 135 via a cross bar of analogue switches 310. In this example, the processor 120 is arranged to re-configure the individual switches 312 of the cross bar of analogue switches 310 in order to connect one or more of the multiple pieces of test equipment to selectable input-output ports 314 of the series (or array) of input-output ports 314 and thereafter to one or more DUTs 135. FIG. 3 illustrates a logical arrangement of the architecture, as might be perceived by a user/operator, e.g., a collection of different instruments multiplexed arbitrarily using a switch matrix in a form of a cross bar of analogue switches 310.

In essence, the processor 120 may be able to very quickly re-configure the test equipment functionality, often masking the re-configuration complexity from the operator/test engineer. In some examples, the processor 120 may be able to present the operator/test engineer with an easy to use/understand interface, using for example the personal computer or laptop or controller and user interface 110 and thereby the user (e.g., operator/test engineer) is able to manage the complex test equipment set-up behind that user interface 110 using the user interface, the processor 120 and its associated software-based control of the software configurable switch, which in this example is a cross bar of analogue switches 310. In this manner, new features may be easier to create due to the multiplicity of simple building blocks that lends itself to creation of new instruments through simple software updates. For example, currently, an operator/test engineer may place an oscilloscope and a power supply in a box and add some switches to the front end, but the combination will always be just an oscilloscope and power supply. However, by adopting the system architecture 300 of FIG. 3, it is envisaged that a multitude of options exist, such as adding a collection of DACs and ADCs to configurable logic, which could be the previously mentioned oscilloscope and power supply. In this manner, the test equipment can be re-configured in a plethora of ways and its capabilities increased, substantially exponentially. In this manner, it is possible to very quickly re-configure the individual switches 312 of the cross bar of analogue switches 310 in order to connect one or more of the multiple pieces of test equipment to selectable input-output ports 314 to form, say, a network analyser, or a DMM or a logic analyser or some combination of the above, as would be appreciated by a skilled operator/test engineer.

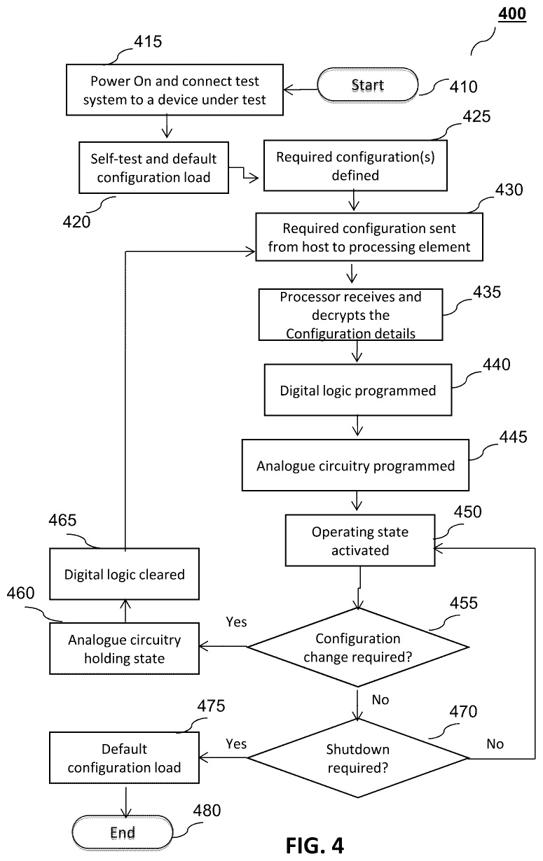

Referring now to FIG. 4, an example flowchart 400 is illustrated of a mechanism for dynamically (re-)configuring the electronic test equipment system of FIG. 1 and/or FIG. 2 and/or FIG. 3. In some examples, the dynamic (re-)configuring may include (re-)configuring of connections within the electronic test equipment system and/or connections between the electronic test equipment system and a device-under-test through software control of a software configurable analogue switch, adapted according to examples herein described. The example flowchart 400 of the dynamically (re-)configuring of the electronic test equipment system starts at 410 with a system power ‘on’ performed at 415 and connecting the electronic test equipment system to a device under test. At 420, in some examples, a processor in the electronic test equipment system, e.g., signal processor 120 of FIG. 1, performs one or more self-tests, for example the processor may set/configure electronic test equipment system digital-to-analog converters (DACs) and measure their performance and compare with its own analog-to-digital converters (ADCs), perform tests for internal communications to internal hardware systems, etc. Furthermore, in some examples, the processor in the electronic test equipment system may configure the electronic test equipment system to a simple ‘inactive’ (i.e., do-nothing) state, by loading the electronic test equipment system with a default configuration, for example where the input-output (IO) pins are set to high impedance to prevent damage to any unknown attached DUT. In some examples, it is envisaged that the digital and analogue configurable logic may have images loaded (or pre-installed) to facilitate internal self-test. In some examples, such a self-test may be arranged to mainly loop back the internal ADCs and DACs to each other, rather than using the DUT as it may not be present. Hence, it may be viewed as disconnecting the DUT loop or the ADCs to the DACs in various ways, and to feed a test signal out of the DACs check the ADCs receive the test signal within some control limits. It is envisaged that the accuracy of this process may result from factory calibration and regular interval service calibration, akin to any other bench instrument.

At 425, in some examples, a user or the electronic test equipment system operator or control software selects one or more desired configuration(s) of the electronic test equipment system and optionally defines what triggers may cause an automated change between those configurations. At 430, an initial (first or subsequent) configuration is transferred to the processor (and if encrypted an encryption/decryption circuit within the processor decrypts the configuration therein at 435). At 440, a decrypted digital logic image is transferred to the dynamically configurable digital logic. In some examples, the processor may also apply/program a secondary part of the decrypted image to dynamically configurable analogue circuitry within the electronic test equipment system at 445. The inventor has recognised and appreciated that there is a benefit in splitting the configuration details between digital and analogue circuits as they are fundamentally different systems and as such would benefit from their own respective unique configuration images.

At 450, the digital and analogue circuitry are moved to an operating state whereby data is transferred as defined by the configuration image, both between them and the processor. In this regard, the electronic test equipment system is performing a measurement of the device-under-test using the re-configured dynamically configurable digital logic and/or dynamically configurable analogue circuitry. The data is then subsequently transferred back to the user, operator or control software.

A determination is then made as to whether (or not) a new configuration is required at 455 (for example from either from a trigger or user or operator or host software intervention). If a new configuration is required at 455, the processor places the analogue circuitry into a holding state at 460, where the analogue circuitry is not fully operational but still able to function at a basic level, e.g., continuing to operate as it was currently doing. Thereafter, at 465, the processor resets the digital logic and then the flowchart loops to 430 and the process repeats, as necessary. Alternatively, if a new configuration is not required at 455, the processor transitions to a determination as to whether (or not) a shutdown of the electronic test equipment system is required at 470. If a shutdown of the electronic test equipment system is not required at 470, the flowchart loops to 450 and the process repeats, as necessary. If a shutdown of the electronic test equipment system is required at 470, a default configuration is loaded into the electronic test equipment system at 475 and the flowchart ends at 480.

In this manner, as described in the examples above, an implementation that employs very configurable analogue and digital circuitry, with various DACs and ADCs and a switch matrix, say in a form of a cross-bar switch matrix 310, can achieve significant flexibility and improvements in test instrumentation, only limited by the technical performance of the configurable analogue and digital circuitry as to what can be tested. Advantageously, a majority of the instrumentation is “soft”, in that it is programmable, such that entirely new instruments may be added merely through providing a new “configuration image” for the device and dynamically reconfiguring the instances of those instruments based upon the host/controlling software and measured events.

In the foregoing specification, the invention has been described with reference to specific examples of embodiments of the invention. It will, however, be evident that various modifications and changes may be made therein without departing from the scope of the invention as set forth in the appended claims and that the claims are not limited to the specific examples described above.

The connections as discussed herein may be any type of connection suitable to transfer signals from or to the respective nodes, units or devices, for example via intermediate devices. Accordingly, unless implied or stated otherwise, the connections may for example be direct connections or indirect connections. The connections may be illustrated or described in reference to being a single connection, a plurality of connections, unidirectional connections, or bidirectional connections. However, different embodiments may vary the implementation of the connections. For example, separate unidirectional connections may be used rather than bidirectional connections and vice versa. Also, plurality of connections may be replaced with a single connection that transfers multiple signals serially or in a time multiplexed manner. Likewise, single connections carrying multiple signals may be separated out into various different connections carrying subsets of these signals. Therefore, many options exist for transferring signals. Those skilled in the art will recognize that the architectures depicted herein are merely exemplary, and that in fact many other architectures can be implemented which achieve the same functionality.

Any arrangement of components to achieve the same functionality is effectively ‘associated’ such that the desired functionality is achieved. Hence, any two components herein combined to achieve a particular functionality can be seen as ‘associated with’ each other such that the desired functionality is achieved, irrespective of architectures or intermediary components. Likewise, any two components so associated can also be viewed as being ‘operably connected,’ or ‘operably coupled,’ to each other to achieve the desired functionality.

Furthermore, those skilled in the art will recognize that boundaries between the above-described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. Also, for example, in one embodiment, the illustrated examples may be implemented as circuitry located on a single integrated circuit or within a same device. For example, crossbar switch circuit 310 coupled to (or couplable to) a plurality of IO ports 314 and connectable to a plurality of test equipment devices and circuits.

As the illustrated embodiments of the present invention may, for the most part, be implemented using electronic components and circuits known to those skilled in the art, details will not be explained in any greater extent than that considered necessary as illustrated below, for the understanding and appreciation of the underlying concepts of the present invention and in order not to obfuscate or distract from the teachings of the present invention. A skilled artisan will appreciate that the level of integration of circuits or components may be, in some instances, implementation-dependent.

Also, for example, the examples, or portions thereof, may implemented as soft or code representations of physical circuitry or of logical representations convertible into physical circuitry, such as in a hardware description language of any appropriate type. Also, the invention is not limited to physical devices or units implemented in non-programmable hardware but can also be applied in programmable devices or units able to perform the desired sampling error and compensation by operating in accordance with suitable program code, such as minicomputers, personal computers, notepads, personal digital assistants, automotive and other embedded systems, cell phones and various other wireless devices, commonly denoted in this application as ‘computer systems’. However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps then those listed in a claim. Furthermore, the terms ‘a’ or ‘an,’ as used herein, are defined as one or more than one. Also, the use of introductory phrases such as ‘at least one’ and ‘one or more’ in the claims should not be construed to imply that the introduction of another claim element by the indefinite articles ‘a’ or ‘an’ limits any particular claim containing such introduced claim element to inventions containing only one such element, even when the same claim includes the introductory phrases ‘one or more’ or ‘at least one’ and indefinite articles such as ‘a’ or ‘an.’ The same holds true for the use of definite articles. Unless stated otherwise, terms such as ‘first’ and ‘second’ are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

We claim:

1. An electronic test equipment system comprising:
a user interface;
a dynamically configurable multi-instrument operably coupleable to the user interface and comprising:
a processor;
an input-output (IO), interface configurable to be connected to a device under test (DUT);
a software configurable switch operably coupled to and configurable by the processor; and
at least one of: dynamically configurable digital logic circuitry, dynamically configurable analogue circuitry, coupled to the software configurable switch and the processor; and
wherein the dynamically configurable multi-instrument is arranged to receive configuration details from the user interface and, in response thereto, the processor is arranged to apply at least one control signal to the software configurable switch that connects at least one selectable item of test equipment of at least one of: the dynamically configurable digital logic circuitry, dynamically configurable analogue circuitry, to at least one individual IO of the IO interface that re-configures the dynamically configurable multi-instrument to function as a different measurement or test instrument for the DUT.

2. The electronic test equipment system of claim 1, wherein the dynamically configurable multi-instrument comprises dynamically configurable digital logic circuitry that comprises digital test instrumentation equipment and dynamically configurable analogue circuitry that comprises analogue test instrumentation equipment.

3. The electronic test equipment system of claim 2, wherein a plurality of test equipment items of the instrumentation equipment is selectably connected to the DUT via the software configurable switch and individual IOs of the IO interface.

4. The electronic test equipment system of claim 1, wherein the software configurable switch is a populated crossbar switch located between a plurality of selectable items of test equipment of the at least one of: dynamically configurable digital logic circuitry, dynamically configurable analogue circuitry, and individual IO of the IO interface.

5. The electronic test equipment system of claim 1, wherein the dynamically configurable digital logic circuitry and dynamically configurable analogue circuitry comprise instrumentation equipment that is configurable via the processor in response to a test equipment image provided by the user interface.

6. The electronic test equipment system of claim 5, wherein the processor comprises a decryption circuit arranged to decrypt an encrypted digital logic image input to the user interface and transfer a decrypted digital logic image to the dynamically configurable digital logic circuitry.

7. The electronic test equipment system of claim 1, wherein the processor is arranged to generate a waveform to be applied to a first selectable item of test equipment of at least one of: the dynamically configurable digital logic circuitry, dynamically configurable analogue circuitry in response to at least one measurement of the DUT performed by a second selectable item of test equipment.

8. The electronic test equipment system of claim 1, wherein the IO interface comprises an array of IO ports configured connectable to multiple ports of DUT.

9. The electronic test equipment system of claim 1, wherein the at least one selectable item of test equipment of at least one of: the dynamically configurable digital logic circuitry, dynamically configurable analogue circuitry, is selected on a time-limited or a capability limited license.

10. The electronic test equipment system of claim 1, wherein the processor is arranged to transfer a plurality of signals to the user interface that indicate a current set-up of the at least one selectable item of test equipment of at least one of: the dynamically configurable digital logic circuitry, dynamically configurable analogue circuitry, and connections to the at least one individual IO of the IO interface wherein the user interface and processor are arranged to cooperate and enable a test engineer to re-configure the electronic test equipment system via software-based control of the software configurable switch to perform measurements on the DUT.

11. An integrated circuit for an electronic test equipment system, the integrated circuit comprising a software (SW), configurable switch responsive to at least one control signal that connects at least one selectable item of test equipment of at least one of: dynamically configurable digital logic circuitry, dynamically configurable analogue circuitry, to at least one individual input-output (IO) of an IO interface that re-configures the electronic test equipment system to function as a different measurement or test instrument for a device under test (DUT).

12. A method for performing electronic instrumentation testing and/or control of a device-under-test (DUT), the method comprising:
connecting a dynamically configurable multi-instrument to a device under test via a software, SW, configurable switch operably couplable to and configurable by a processor;
receiving configuration details for the dynamically configurable multi-instrument, wherein the dynamically configurable multi-instrument comprises at least one of: dynamically configurable digital logic circuitry, dynamically configurable analogue circuitry;
applying at least one control signal to the software configurable switch that connects at least one selectable item of test equipment of at least one of: the dynamically configurable digital logic circuitry, dynamically configurable analogue circuitry, to at least one individual input-output (IO) port of an IO interface that re-configures the dynamically configurable multi-instrument to function as a different measurement or test instrument for the DUT; and
performing a measurement of the DUT using the re-configured dynamically configurable digital logic and/or dynamically configurable analogue circuitry.

13. The method of claim 12, wherein receiving configuration details for the dynamically configurable multi-instrument comprises receiving configuration details for dynamically configurable digital logic circuitry that comprises digital test instrumentation equipment and receiving configuration details for dynamically configurable analogue circuitry that comprises analogue test instrumentation equipment.

14. The method of claim 13, further comprising selectably connecting a plurality of test equipment items of the instrumentation equipment to the DUT via the software configurable switch and individual IOs of the IO interface.

15. The method of claim 12, wherein the software configurable switch is a populated crossbar switch located between a plurality of selectable items of test equipment of the at least one of: dynamically configurable digital logic circuitry, dynamically configurable analogue circuitry, and individual IO of the IO interface.

16. The method of claim 12, wherein the dynamically configurable digital logic circuitry and dynamically configurable analogue circuitry comprise instrumentation equipment that is configurable via the processor in response to a test equipment image provided by the user interface.

17. The method of claim 16, further comprising decrypting by a decryption circuit of the processor an encrypted digital logic image input to the user interface and transferring a decrypted digital logic image to the dynamically configurable digital logic circuitry.

18. The method of claim 12, further comprising generating a waveform by the processor and applying the waveform to a first selectable item of test equipment of at least one of: the dynamically configurable digital logic circuitry, dynamically configurable analogue circuitry in response to at least one measurement of the DUT performed by a second selectable item of test equipment.

19. The method of claim 12, wherein the IO interface comprises an array of IO ports configured connectable to multiple ports of the DUT.

20. The method of claim 12, further comprising selecting on a time-limited or a capability limited license the at least one selectable item of test equipment of at least one of: the dynamically configurable digital logic circuitry, dynamically configurable analogue circuitry.
